(19) United States
(12) Patent Application Publication
(10) Pub. No.: US 2025/0393177 A1
(43) Pub. Date: Dec. 25, 2025

(54) DISPLAY DEVICE COMPRISING ELECTRONIC COMPONENT AND THERMOELECTRIC ELEMENT TO CONVERT HEAT OF ELECTRONIC COMPONENT TO ELECTRICAL ENERGY AND METHOD THEREOF

(71) Applicant: Samsung Electronics Co., Ltd., Suwon-si (KR)

(72) Inventors: Sungyong JOO, Suwon-si (KR); Sungbum JUNG, Suwon-si (KR); Shinho KANG, Suwon-si (KR); Jeongwoo KIM, Suwon-si (KR)

(21) Appl. No.: 19/086,405

(22) Filed: Mar. 21, 2025

Related U.S. Application Data
(63) Continuation of application No. PCT/KR2025/002931, filed on Mar. 5, 2025.

(30) Foreign Application Priority Data
Jun. 25, 2024 (KR) 10-2024-0083196

(51) Int. Cl. H05K 7/20; G06F 1/26; G06F 1/3218

(52) U.S. Cl. CPC H05K 7/20963; G06F 1/263; G06F 1/266; G06F 1/3218

(57) ABSTRACT

According to an embodiment, a display device includes: a display panel, a printed circuit board (PCB), a heat generating element comprising an electronic component including various circuitry coupled on the PCB and configured to emit heat based on driving of the display panel, a chassis positioned on a surface of the display panel, including a heat dissipation portion adjacent to the heat generating element, and a support portion configured to support the PCB, a thermoelectric element including at least one electrode interposed between the heat generating element and the heat dissipation portion, including a first surface in contact with the heat generating element and a second surface in contact with the heat dissipation portion, and a battery connected to the thermoelectric element. The thermoelectric element is configured to charge the battery based on a temperature difference between a first temperature of the first surface, associated with the heat emitted from the heat generating element, and a second temperature of the second surface, which is lower than the first temperature by the heat dissipation portion.

### CROSS-REFERENCE TO RELATED APPLICATIONS

This application is a continuation of International Application No. PCT/KR2025/002931 designating the United States, filed on Mar. 5, 2025, in the Korean Intellectual Property Receiving Office and claiming priority to Korean Patent Application No. 10-2024-0083196, filed on Jun. 25, 2024, in the Korean Intellectual Property Office, the disclosures of each of which are incorporated by reference herein in their entireties.

### BACKGROUND

### Field

The disclosure relates to a display device comprising an electronic component and a thermoelectric element to convert heat of the electronic component to electrical energy and a method thereof.

### Description of Related Art

A display device is being advanced with advancements in electronic technology. In order to provide a clear image, there is an increasing demand for the display device having a wider size. In order to support various functions, the number and complexity of an electronic component included in the display device are increasing.

The above-described information may be provided as a related art for the purpose of helping understanding of the present disclosure. No assertion or decision is made as to whether any of the above description may be applied as a prior art related to the present disclosure.

### SUMMARY

According to an example embodiment, a display device may comprise: a display panel, a printed circuit board (PCB), a heat generating element comprising an electronic component comprising circuitry coupled to the PCB and configured to emit heat based on driving of the display panel, a chassis positioned on a surface of the display panel, including a heat dissipation element comprising a thermally conductive material adjacent to the heat generating element, and a support portion configured to support the PCB, a thermoelectric element comprising at least one electrode and interposed between the heat generating element and the heat dissipation element, including a first surface in contact with the heat generating element and a second surface in contact with the heat dissipation element, and a battery connected to the thermoelectric element. The thermoelectric element may be configured to charge the battery, based on a temperature difference between a first temperature of the first surface, associated with the heat emitted from the heat generating element, and a second temperature of the second surface, which is less than the first temperature by the heat dissipation element.

According to an example embodiment, a display device may comprise: a controller comprising circuitry, power circuitry configured to obtain electric power from a power system of an outside of the display device for driving of the display device, an infrared (IR) sensor, a display panel, a thermoelectric element comprising at least one electrode configured to at least partially convert heat energy of at least one of the controller or the power circuitry into electric energy, and a battery configured to store the electric energy. The controller may be configured to receive a first input to cease provision of an image through the display panel. The controller may be configured to, based on the first input, deactivate the display panel and the power circuitry. The controller may be configured to, based on the deactivation, activate the IR sensor using the electric energy stored in the battery to detect a second input to start provision of an image through the display panel through the IR sensor.

In an example embodiment, a method of controlling or operating a display device may be provided. The display device may comprise power circuitry configured to obtain power for driving of the display device from a power system of an outside of the display device, an infrared (IR) sensor, a display panel, a thermoelectric element configured to at least partially convert heat energy of at least one of the power circuitry to electric energy, and a battery configured to store the electric energy. The method may comprise receiving a first input to cease provision of an image through the display panel. The method may comprise, based on the first input, deactivating the power circuitry and the display panel. The method may comprise, based on the deactivation, activating the IR sensor using the electric energy stored in the battery to detect, through the IR sensor, a second input to start provision of an image through the display panel.

### BRIEF DESCRIPTION OF THE DRAWINGS

The above and other aspects, features and advantages of certain embodiments of the present disclosure will be more apparent from the following detailed description, taken in conjunction with the accompanying drawings, in which:

FIG. 1 is a diagram illustrating an example display device according to various embodiments;

FIG. 2 is a block diagram illustrating an example configuration of a display device according to various embodiments;

FIG. 3 is a cross-sectional view illustrating a plurality of thermoelectric elements included in a display device according to various embodiments;

FIG. 4 is an exploded perspective view of a display device according to various embodiments;

FIGS. 5A, 5B, and 5C are diagrams illustrating example coupling relationships between a thermoelectric element and a heat generating element included in a display device according to various embodiments;

FIGS. 6A, 6B, and 6C are diagrams illustrating an example coupling relationship between a coil assembly and a heat generating element included in a display device according to various embodiments; and

FIGS. 7A, 7B, and 7C are diagrams illustrating example locational relationships of a thermoelectric element and a battery included in a display device according to various embodiments.

### DETAILED DESCRIPTION

Hereinafter, various example embodiments of the disclosure will be described in greater detail with reference to an attached drawing.

It should be understood that various embodiments of the present disclosure and the terms used herein are not intended to limit the disclosure to a particular embodiment and include various changes, equivalents, and/or replacements of a corresponding embodiment. With regard to a description of a drawing, similar reference numerals may be used for a similar component. A singular expression may include a plural expression unless a context clearly indicates otherwise. In the present disclosure, an expression such as “A or B,” “at least one of A and/or B,” “A, B, or C,” or “at least one of A, B, and/or C” may include all possible combinations of items listed together. Expressions such as “1st,” “2nd,” “first,” or “second” may simply modify corresponding components regardless of an order or importance, and may be used to distinguish a component from another, and does not limit the corresponding components. When a component (e.g., a 1st) is mentioned as “(functionally or communicatively) connected” or “linked” to another component (e.g., a 2nd), the component may be directly connected to the another component, or may be connected through another component (e.g., a third component).

The term “module” used in the present disclosure may include a unit configured with hardware, and may interchangeably be used with terms, for example, component, and/or circuitry. A module may be an integrated component, or a minimum unit performing one or more functions or a portion thereof. For example, the module may be configured with an application-specific integrated circuit (ASIC).

In the present disclosure, when an expression (e.g., “on”, “at the top”, “below”, “at the bottom”, and “next to”) for a locational relationship between an element and another element are mentioned, it should be understood that unless expressions such as “rightly” or “directly” are used, one or more intervening elements therebetween two elements may exist, and it should be noted that it does not limit an arrangement relationship between the two elements.

For example, when an element is mentioned as being “on” another element, it may include that one or more intervening elements therebetween may exist other than the element being attached to another element, combined inseparably, or formed inseparably. For example, in the present disclosure, “B positioned on A” may indicate “B positioned over A”. For example, in the present disclosure, “B positioned on A” may indicate “B facing A and spaced apart from A”. For example, “a first plane portion positioned on the first housing part” may indicate “a first plane portion in contact with the first housing part”. For example, “a first plane portion positioned on the first housing part” may indicate “a first plane portion facing the first housing part and spaced apart from the first housing part”.

For example, in the present disclosure, “B on A” may indicate “B at least partially positioned on a surface of A”. For example, in the present disclosure, “B on A” may indicate “B formed in A”. For example, in the present disclosure, “B on A” may refer, for example, to “B in which a portion is formed on a surface of A, and the remaining portion is formed on another surface opposite to the surface of the A”. For example, “B on A” may refer, for example, to “B in which a portion is coupled to an outer surface of A and the remaining portion is coupled to an inside of the A”.

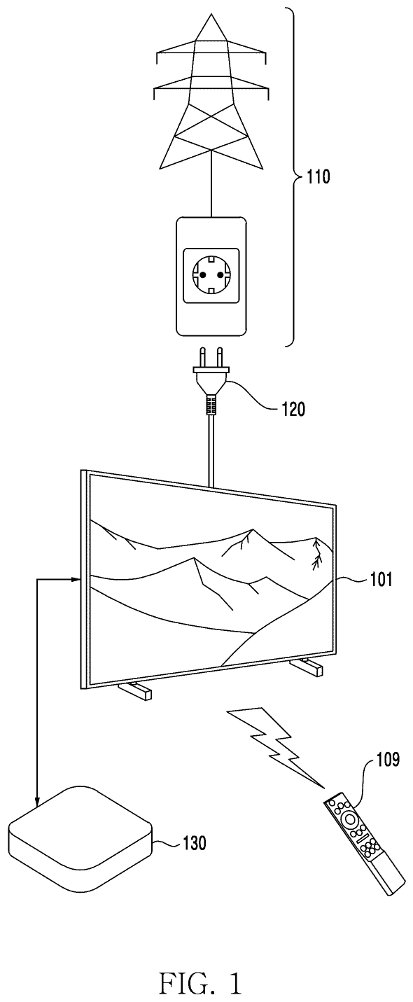

FIG. 1 is a diagram illustrating an example display device 101 according to various embodiments. The display device 101 may be described as an electronic device capable of displaying an image. For example, the display device 101 may include, without limitation, a television (TV), a monitor, a computer, a smartphone, a tablet, a portable media player, a wearable device, a video wall, an electronic frame, and the like. Hereinafter, for convenience of a description, it will be assumed that the display device 101 is implemented as the TV, but the disclosure is not limited thereto.

The display device 101 may be configured to operate by power (e.g., an alternate current (AC) power signal) provided from a power system 110. The display device 101 may include a plug 120 (or electric cord) configured to be connected to a consent (or outlet, a socket, or a receptacle) located at an end of the power system 110. The plug 120 may be connected to a component (e.g., an AC-DC adapter (or an electric adapter)) of the display device 101 for power conversion (e.g., power conversion from the alternate current power signal to a direct current (DC) power signal).

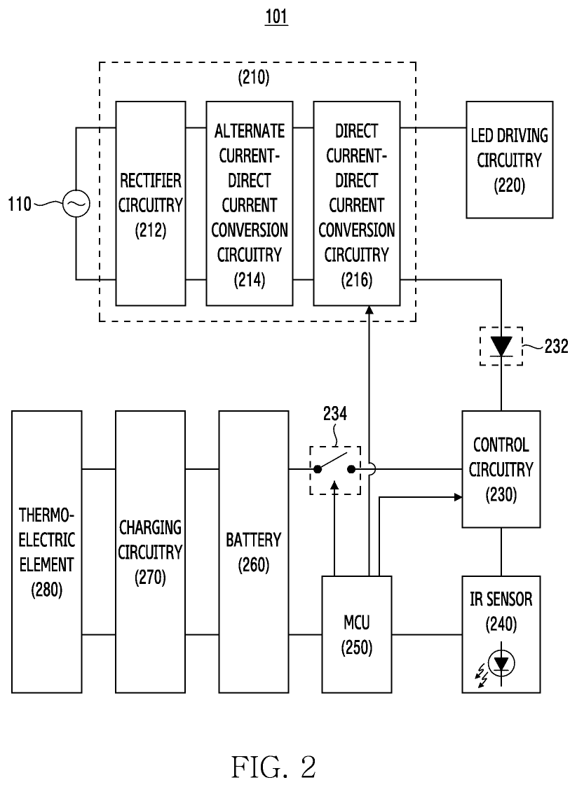

While the plug 120 is electrically connected to the power system 110, the display device 101 may execute a function to output an image, sound, or a combination thereof (e.g., multimedia content) based on the power of the power system 110. When receiving information indicating the image and/or the sound, the display device 101 may execute the function using the information. The information indicating the image and/or the sound may be stored in the display device 101 or received from an external electronic device (e.g., a set-top box (STB) 130) connected to the display device 101. The display device 101 may include an antenna configured to receive the information wirelessly, or may be electrically connected to the antenna. An example hardware configuration included in the display device 101 to process the information will be described in greater detail below with reference to FIG. 2.

A state of the display device 101 while receiving the power of the power system 110 through the plug 120 may include an inactive state (or a power-off state, a power-down state, a shutdown state, or an off state), and an active state (or a power-on state, a power-up state, a standby state, an idle state, or an enabled state). In the inactive state, an output of the image and the sound by the display device 101 may be substantially ceased, or may be minimized and/or reduced. In the inactive state, the display device 101 may output a message (e.g., “press a power button”) guiding an input to switch to the active state. In the active state, the display device 101 may output the image and/or the sound. The display device 101 may switch between the inactive state and the active state, or may toggle, based on a user input.

The display device 101 may include hardware to receive the user input (e.g., the user input to switch between the inactive state and the active state) for control of the display device 101. For example, the display device 101 may include a switch (or a button) that is at least partially visible through a housing of the display device 101. For example, the display device 101 may include a touch sensor (e.g., a pressure sensitive touch sensor and/or a capacitive touch sensor) to detect a touch input on at least a portion of the housing. The user input may include a user's direct action (e.g., an action of pressing the switch and/or the button, or touching a surface of the housing) on the display device 101. The disclosure is not limited thereto, and the user input may include a user's indirect action associated with the display device 101, based on a remote controller 109.

Referring to FIG. 1, the display device 101 may be configured to receive a wireless signal (or an optical signal) of the remote controller 109, based on infrared (IR). An embodiment is not limited thereto, and the remote controller 109 may be configured to transmit the wireless signal, based on Bluetooth, Bluetooth low energy (BLE), near-field communication (NFC), ultra-wideband (UWB), wireless fidelity (WiFi), WiFi-direct, and/or another wireless short-range communication protocol, and the display device 101 may be configured to receive the wireless signal based on the illustrated wireless short-range communication protocol.

Power consumption of the display device 101 may depend on the state (e.g., the inactive state and/or the active state) of the display device 101. For example, in the inactive state, circuitry of the display device 101 configured to output the image and the sound may be at least partially deactivated, since outputting the image and the sound is stopped. By deactivating the circuitry, the power consumption of the display device 101 may be reduced.

The power consumption of the display device 101 in the inactive state may be referred to as standby power. The standby power of the display device 101 may be described as the power consumption of the display device 101 in the inactive state measured from the power system 110 (or the plug 120). The standby power in the inactive state may include the power consumption of the circuitry of a display device that is at least partially activated. In the active state, since circuitry that was deactivated in the inactive state is reactivated, the power consumption of the display device 101 may be increased more than the standby power.

For example, in the inactive state, circuitry to receive (or detect) the user input may be activated in order to receive the user input to switch from the inactive state to the active state. For example, the circuitry may be continuously activated independently of the active state or the inactive state of the display device 101. The standby power of the display device 101 may include the power consumption of the circuitry (e.g., the circuitry to receive the wireless signal of the remote controller 109) configured to receive the user input.

In an embodiment, a method minimizing and/or reducing the standby power of the display device 101 may be required. In order to reduce, minimize, or eliminate the standby power, the display device 101 may store or obtain power to be used in the inactive state in a state (e.g., the active state) distinct from the inactive state. For example, the display device 101 may include an element and/or hardware to store heat of the display device 101, which is generated in the active state. For example, the display device 101 may include an element that generates electric energy from energy (e.g., heat energy) distinct from electric energy, referred to as an energy harvester. The energy harvester may include a piezoelectric element based on a piezoelectric effect, a magnetoelectric element based on a magnetoelectric effect, a piezoelectric element based on a photovoltaic effect, and/or a thermoelectric element based on a thermoelectric effect.

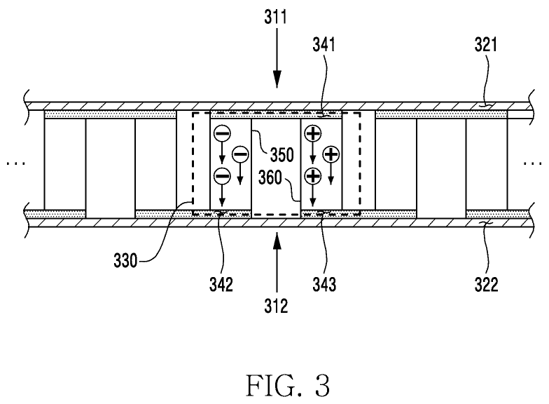

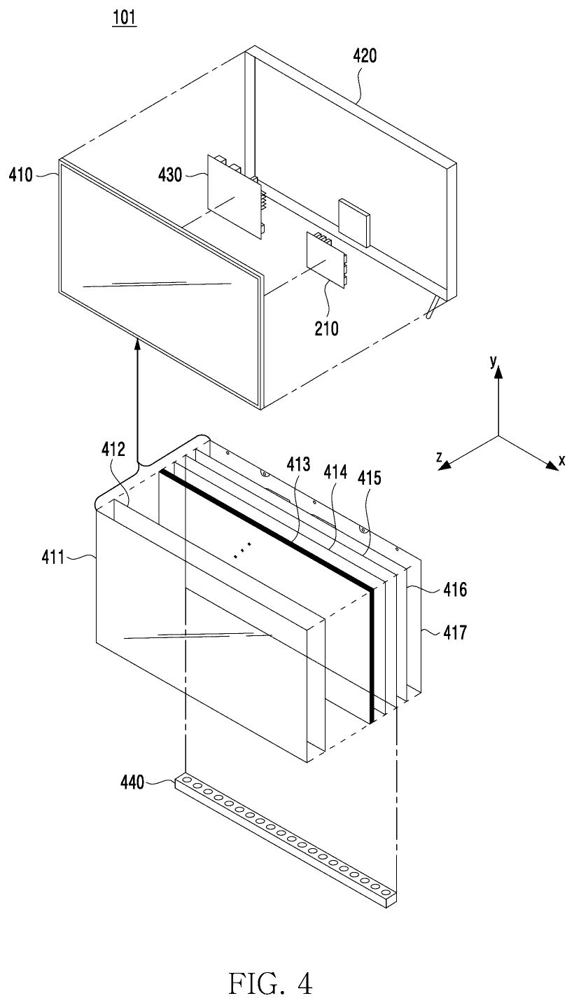

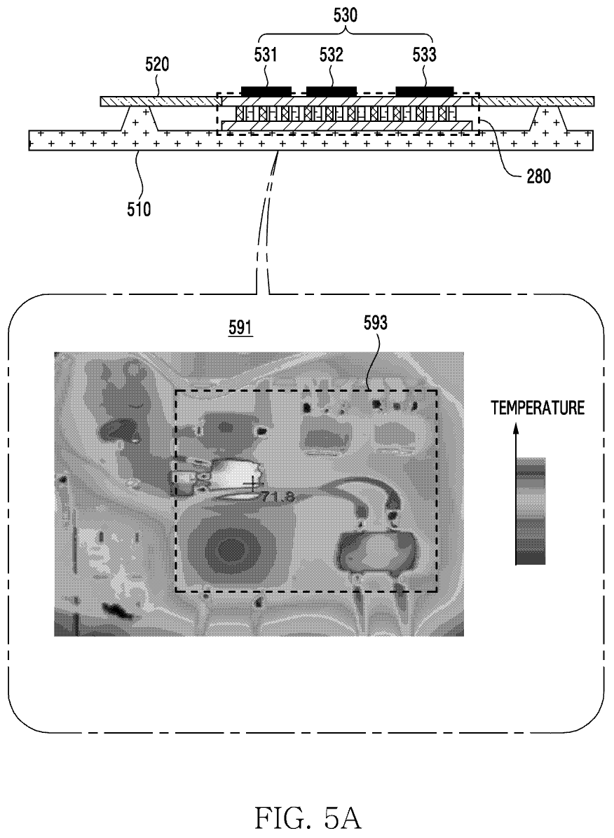

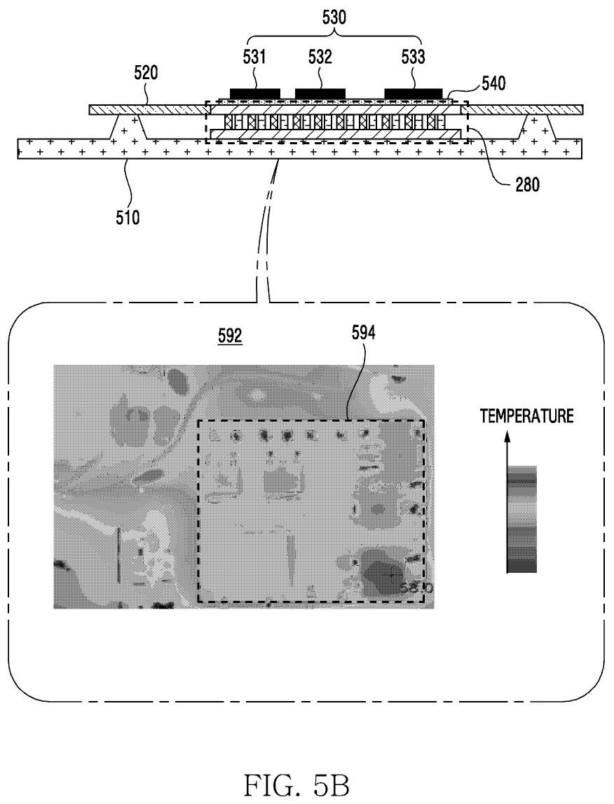

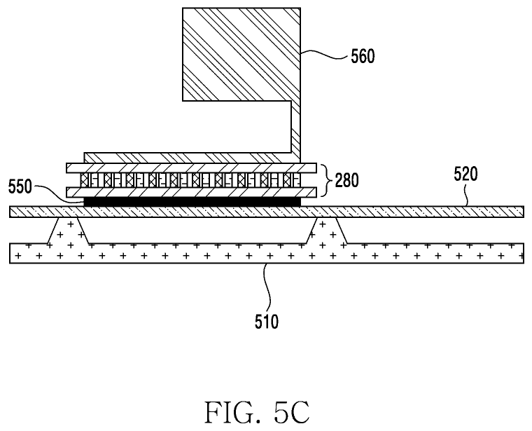

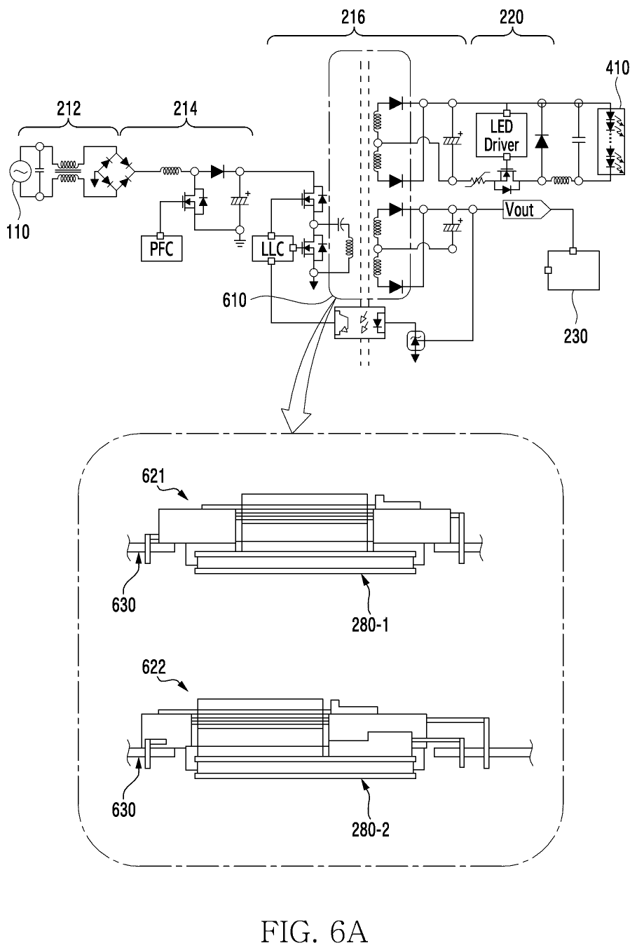

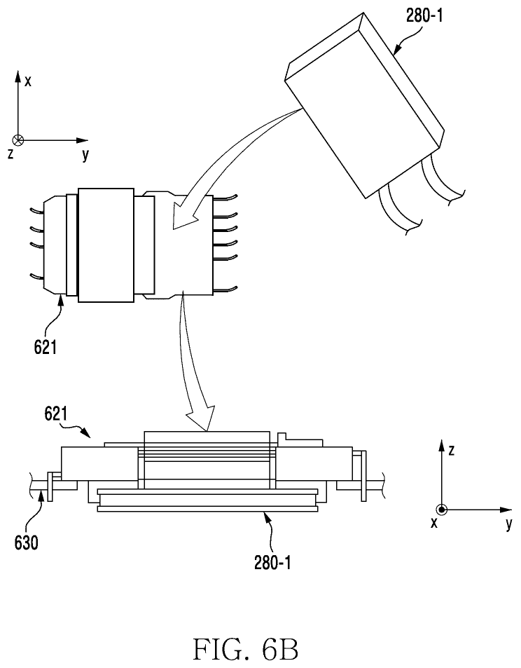

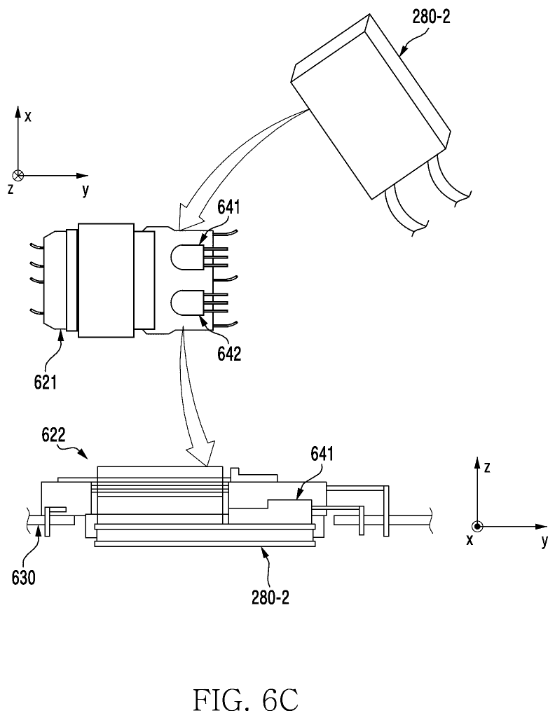

The disclosure may be associated with the display device 101, which includes a thermoelectric element configured to generate electric energy from heat generated by a heat generating element (e.g., an electronic component of the display device 101, activated based on the electric energy) of the display device 101. A coupling relationship of one or more thermoelectric elements included in the display device 101 will be described by way of non-limiting example in greater detail below with reference to FIG. 3. The heat generating element of the display device 101, which generates a relatively large amount of heat, will be illustrated and described in greater detail below with reference to FIG. 4. The locational relationship between the heat generating element and the thermoelectric element will be described in greater detail below with reference to FIGS. 5A, 5B, 5C, 6A, 6B, and/or 6C.

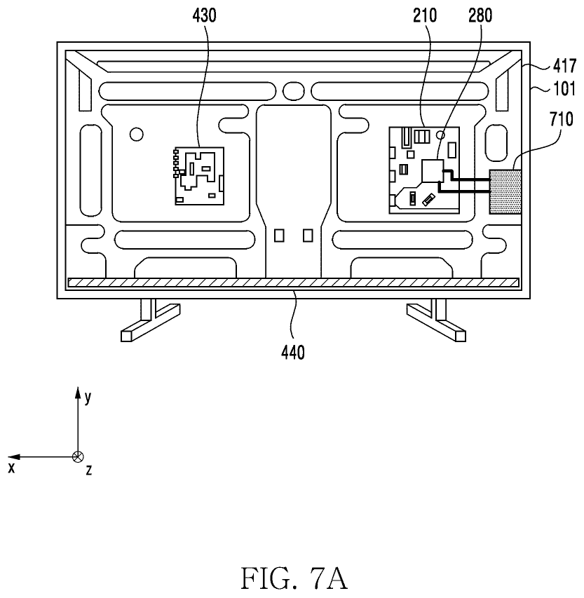

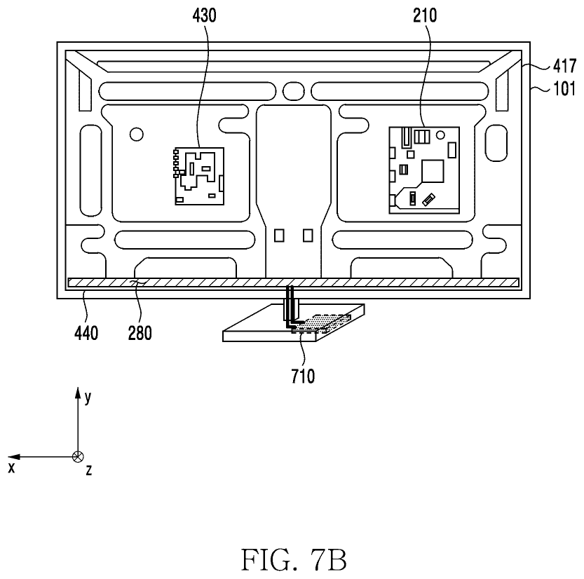

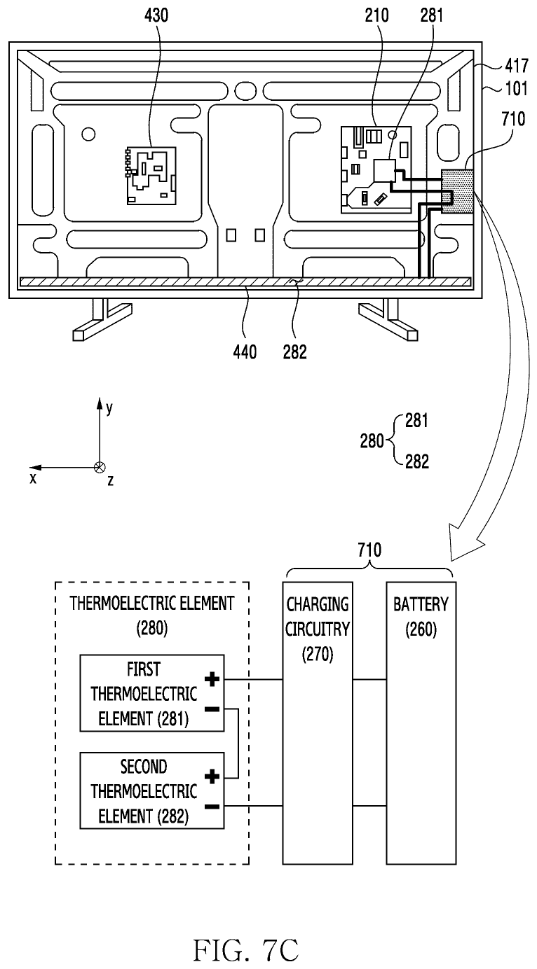

In an embodiment, the display device 101 may include a battery (e.g., a rechargeable battery, referred to as a secondary battery) which is charged by the electric energy generated by the thermoelectric element. Example circuitry formed between the thermoelectric element and the battery will be described in greater detail below with reference to FIG. 2 and/or FIGS. 7A, 7B and 7C. In the active state, the heat generated by the heat generating element may be at least partially converted into the electric energy by the thermoelectric element. The converted electric energy may be stored in the battery. For example, the battery may be charged in the active state. In the inactive state, the display device 101 may operate at least temporarily by the power of the battery.

In the inactive state, since at least a portion (e.g., circuitry to communicate with the remote controller 109) of the circuitry of the display device 101 is activated by the power of the battery among the power of the power system 110 provided through the plug 120 or the power of the battery, the standby power of the display device 101 measured from the power system 110 may be reduced to substantially zero. Despite the standby power being decreased, the display device 101 may maintain to receive the wireless signal from the remote controller 109 using the power of the battery. For example, even after the standby power is reduced to zero, the display device 101 may receive the wireless signal (e.g., an IR signal) output from the remote controller 109 as the user presses a preset button (e.g., a power button) of the remote controller 109. In response to receiving the wireless signal, the display device 101 may switch from the inactive state to the active state.

Hereinafter, an example configuration of the display device 101 including a thermoelectric element will be described in greater detail with reference to FIG. 2.

FIG. 2 is a block diagram illustrating an example configuration of a display device 101 according to various embodiments. The display device 101 of FIG. 2 may include the display device 101 of FIG. 1.

FIG. 2 is a block diagram illustrating portions of circuitry of the display device 101 illustrated as blocks. According to an embodiment, the display device 101 may include power circuitry 210, light emitting diode (LED) driving circuitry 220, control circuitry 230, an IR sensor 240, a microcontroller unit (MCU) (e.g., including control circuitry) 250, a battery 260, charging circuitry 270, a thermoelectric element 280, or any combination thereof. Portions of the circuitry of the display device 101 illustrated as the blocks may be electrically and/or operably connected by a power line and/or a communication bus. The display device 101 may further include another circuitry (e.g., a display panel, a speaker, and/or an illuminance sensor) distinct from the circuitry illustrated in FIG. 2. The display device 101 may include only a portion of the circuitry illustrated as the blocks of FIG. 2.

Referring to FIG. 2, the power circuitry 210 of the display device 101 may include rectifier circuitry 212, alternate current-direct current conversion circuitry 214, and/or direct current-direct current conversion circuitry 216. Although not illustrated, the power circuitry 210 may further include a lightning protection circuitry, a varistor, a surge arrester, an electromagnetic interference (EMI) filter, a power factor conversion circuitry, or any combination thereof.

The rectifier circuitry 212 of the power circuitry 210 may output a rectified alternate current signal by rectifying the alternate current signal provided by a power system 110. In order to rectify the alternate current signal, the rectifier circuitry 212 may include a plurality of diodes forming a bridge circuitry. Half-wave rectification or full-wave rectification based on the plurality of diodes may be performed by the rectifier circuitry 212. An embodiment is not limited thereto, and the rectifier circuitry 212 may be implemented in a non-bridge method.

The alternate current-direct current conversion circuitry 214 of the power circuitry 210 may be configured to output a direct current signal from an alternate current signal rectified by the rectifier circuitry 212. For example, the alternate current-direct current conversion circuitry 214 may include a capacitor charged by the rectified alternate current signal. The capacitor may be a circuit element that stores electric energy based on an electric field. For example, the capacitor may include an electrolytic capacitor, a tantalum capacitor, a ceramic capacitor, and/or a film capacitor. The capacitor of the alternate current-direct current conversion circuitry 214 may be referred to as a bulk capacitor and/or a super capacitor. When the capacitor is charged by the rectified alternate current signal, a voltage between both ends of the capacitor may be smoothened.

The power circuitry 210 may include the direct current-direct current conversion circuitry 216 configured to output a plurality of direct current signals from the direct current signal output from the alternate current-direct current conversion circuitry 214. The plurality of direct current signals may each have distinct voltages required for driving of electronic components (e.g., load circuitry) included in the display device 101. The direct current-direct current conversion circuitry 216 may include inverter circuitry configured to output the alternate current signal from the direct current signal output from the alternate current-direct current conversion circuitry 214, and a plurality of inductors (e.g., coils, and an assembly of the coils) configured to receive the alternate current signal of the inverter circuitry. The plurality of inductors may include a primary coil that receives the alternate current signal of the inverter circuitry, and a secondary coil that is mutually coupled with the primary coil. The rectifier circuitry and the capacitor connected to the secondary coil may be configured to output the direct current signal required for driving of the electronic component connected to the secondary coil from the alternate current signal generated from the secondary coil.

Referring to FIG. 2, example electronic components (e.g., the LED driving circuitry 220 and/or the control circuitry 230) of the display device 101 configured to receive the direct current signals output from the direct current-direct current conversion circuitry 216 are illustrated. The LED driving circuitry 220 may include circuitry for driving a light source of the display device 101 referred to as backlight. The LED driving circuitry 220 may maintain or change brightness (or luminance) of a plurality of LEDs (e.g., LEDs included in a backlight component) included in the display device 101. For example, the LED driving circuitry 220 may generate or change voltages and/or currents applied to each of the plurality of LEDs. The voltages and/or the currents may be determined by the control circuitry 230.

Although not illustrated, the direct current-direct current conversion circuitry 216 may be electrically connected with a component (e.g., the display panel) of the display device 101 configured to output an image. The display panel may include a liquid crystal display (LCD), a plasma display panel (PDP), and the plurality of LEDs. The LED of the display panel may include an organic LED (OLED). In an embodiment, the display panel may include electronic paper. In case that the display panel has a planar shape, the display panel may be referred to as a flat panel display (FPD). In case that the display panel has a curved shape, the display panel may be referred to as a curved display. In case that the display panel has a deformable shape, the display panel may be referred to as a bendable display, a flexible display, and/or a rollable display.

Although not illustrated, the direct current-direct current conversion circuitry 216 may be electrically connected with one or more speakers configured to output voice. The one or more speakers may be configured to output an audio signal (e.g., an audio signal synchronized with an image to be displayed through the display panel). The control circuitry 230 included in the display device 101 may control the display panel and the one or more speakers substantially simultaneously to simultaneously output an image and a sound associated with the image.

Referring to FIG. 2, according to an embodiment, the display device 101 may include control circuitry 230 to drive another electronic component of the display device 101, such as the display panel and/or the one or more speakers. The control circuitry 230 may be configured to provide the direct current signal of a preset voltage (e.g., 13 V) to another electronic component (e.g., the IR sensor 240). The control circuitry 230 may obtain or process information (e.g., information received from the set-top box 130 of FIG. 1) input to the display device 101. The control circuitry 230 may control the display panel using the information in order to output an image through the display panel. The control circuitry 230 may control the one or more speakers, using the information, to output the sound through the one or more speakers. In the present disclosure, the control circuitry 230 may be referred to as main circuitry, a main board, and/or a primary circuitry.

In an embodiment, the control circuitry 230 may be electrically connected with the electronic component to obtain a user input. The electronic component to obtain the user input may include a switch at least partially exposed through a housing of the display device 101. The electronic component to obtain the user input may include a touch sensor to detect a touch input on at least a portion of the housing of the display device 101.

Referring to FIG. 2, as an example of the electronic component to obtain the user input, the IR sensor 240 is illustrated. In response to receiving and/or detecting an optical signal having a wavelength in the infrared, the IR sensor 240 may be configured to output an electric signal indicating intensity of the optical signal. The control circuitry 230 may obtain or identify information associated with the user input detected by an external electronic device (e.g., the remote controller 109 of FIG. 1) that outputs the optical signal, using the electric signal output from the IR sensor 240. Using the information, the control circuitry 230 may control another electronic component of the display device 101 in order to execute a function associated with the user input. In order to control the another electronic component of the display device 101, the control circuitry 230 may include a processor and/or memory. The control circuitry 230 may include a System-on-Chip (SoC). The processor may include various processing circuitry and/or multiple processors. For example, as used herein, including the claims, the term “processor” may include various processing circuitry, including at least one processor, wherein one or more of at least one processor, individually and/or collectively in a distributed manner, may be configured to perform various functions described herein. As used herein, when “a processor”, “at least one processor”, and “one or more processors” are described as being configured to perform numerous functions, these terms cover situations, for example and without limitation, in which one processor performs some of recited functions and another processor(s) performs other of recited functions, and also situations in which a single processor may perform all recited functions. Additionally, the at least one processor may include a combination of processors performing various of the recited/disclosed functions, e.g., in a distributed manner. At least one processor may execute program instructions to achieve or perform various functions.

In an active state, the control circuitry 230 and/or the IR sensor 240 may be driven by power provided by the power circuitry 210. The power of the power circuitry 210 may be supplied to the electronic component of the display device 101 to drive at least a portion of the electronic component included in the display device 101. The electronic component may emit heat when operated by the power. In terms of emitting the heat, the electronic component may be referred to as a heat generating element. The heat generating element that emits a relatively large amount of heat in the display device 101 may include, for example, and without limitation, a coil assembly included in the power circuitry 210, the backlight component controlled by the LED driving circuitry 220, and/or the processor (and/or SoC) of the control circuitry 230 configured to control the electronic component.

Referring to FIG. 2, according to an embodiment, the display device 101 may include the thermoelectric element 280 configured to at least partially convert the heat (or heat energy) emitted from the heat generating element into the electric energy. The number of thermoelectric elements 280 included in the display device 101 may vary according to an embodiment. In an embodiment in which the display device 101 includes a plurality of thermoelectric elements, the plurality of thermoelectric elements may be coupled in series with each other. A potential difference and/or a current between electrodes of the thermoelectric element may be generated by a temperature difference between two opposite surfaces of the thermoelectric element. In case that the thermoelectric elements are coupled in series, a power signal having a synthesized voltage in which potential differences of the thermoelectric elements are coupled may be generated. The thermoelectric element(s) will be described in greater detail below.

Referring to FIG. 2, according to an embodiment, the display device 101 may include the charging circuitry 270 coupled with the thermoelectric element 280. In an embodiment in which the display device 101 includes the plurality of thermoelectric elements that are coupled in series to each other, the charging circuitry 270 may receive the power signal having the synthesized voltage of voltages generated from the plurality of thermoelectric elements. Since a voltage of the thermoelectric element 280 and/or a flow of a current generated by the thermoelectric element 280 are relatively small, the charging circuitry 270 may output a voltage and/or a current of a suitable size to charge the battery 260 from the voltage and/or the current. For example, the charging circuitry 270 may be configured to control charging of the battery 260 based on the power generated by the thermoelectric element 280. Using the power signal, the charging circuitry 270 may determine or change the voltage and/or the current to be transmitted to the battery 260 of the display device 101. For example, the charging circuitry 270 may be configured to adjust the current input to the battery 260 to maintain generation of the power in the thermoelectric element 280.

Referring to FIG. 2, according to an embodiment, the display device 101 may include a battery 260 coupled with the charging circuitry 270. The battery 260 may be a rechargeable battery by the charging circuitry 270. The battery 260 may output electric energy required for driving of the electronic component of the display device 101 from chemical energy. The battery 260 may include a battery cell, a battery module, or a battery pack. The battery 260 may be any one of a Li-ion battery, a Li-ion polymer battery, a lead storage battery, a NiCd battery, and a NiMH storage battery.

The charging circuitry 270 may determine a voltage and/or a current of the power signal to be transmitted to the battery 260, based at least on an output current limit and/or an output voltage limit of the thermoelectric element 280. For example, the charging circuitry 270 may limit the current of the power signal to be transmitted to the battery 260 so that the current flow of the thermoelectric element 280 is not interrupted. In the active state, the battery 260 may be charged by the heat generated from the heat generating element corresponding to the thermoelectric element 280.

In the active state, the heat generating element (or the electronic component) of the display device 101 including the control circuitry 230 may receive power provided by the power circuitry 210. For example, a direct signal output from the power circuitry 210 may be transmitted to the control circuitry 230 through a diode 232. An anode of the diode 232 may be connected to the direct current-direct current conversion circuitry 216, and a cathode of the diode 232 may be connected to the control circuitry 230.

In the active state, the control circuitry 230 driven by the power provided by the power circuitry 210 may receive a user input to switch from the active state to an inactive state, using the IR sensor 240 (or a switch, and/or a button that is visible on the housing of the display device 101). In response to receiving the user input, the control circuitry 230 may at least temporarily deactivate or turn off the power circuitry 210, the LED driving circuitry 220, the display panel, and/or one or more speakers. The user input may include an input to cease provision of an image through the display panel (or cease provision of sound through one or more speakers). Based on the user input, the control circuitry 230 and/or the MCU 250 may deactivate the power circuitry 210 and the display panel. For example, the control circuitry 230 and/or the MCU 250 may control the power circuitry 210 to start electric isolation between the power system 110 and the display device 101. Based on the user input, the control circuitry 230 and/or the MCU 250 may be configured to activate the IR sensor 240 using the electric energy stored in the battery 260 to detect an input to start provision of an image through the display panel through the IR sensor 240.

For example, when switching from the active state to the inactive state, the MCU 250 and/or the control circuitry 230 may deactivate the power circuitry 210 and/or the display panel. Since the power circuitry 210 is deactivated, standby power of the display device 101 may be substantially reduced to zero. Since the power circuitry 210 is deactivated, the electric isolation between the power system 110 and the display device 101 may occur. Due to the electric isolation, the display panel may be deactivated. The electric isolation may be established to reduce the standby power of the display device 101, which is measured from the power system 110 after being switched from the active state to the inactive state.

When switching from the active state to the inactive state, the control circuitry (e.g., MCU) 250 may activate a switch 234 to electrically connect the battery 260 and the control circuitry 230 (or the IR sensor 240). The switch 234 may include a relay switch and/or a transistor. The transistor may include a bipolar junction transistor (BJT) and/or a field-effect transistor (FET) (e.g., a n-channel metal-oxide semiconductor FET (N-MOSFET), and/or a p-channel MOSFET (P-MOSFET)). By the switch 234, a direct current signal output from the battery 260 may be transmitted to the control circuitry 230 and/or the IR sensor 240. For example, an electric connection between the battery 260 and at least a portion (e.g., the IR sensor 240) of the electronic component of the display device 101 may be established by the switch 234. In the inactive state in which the power circuitry 210 is deactivated, the IR sensor 240 and/or the MCU 250 may be activated by power of the battery 260. When switching from the active state to the inactive state, the MCU 250 may control the control circuitry 230 to cease an output of the direct current signal (e.g., the direct current signal having a voltage of 13 V). Instead of the direct current signal output from the control circuitry 230, the IR sensor 240 may receive the power of the battery 260.

Referring to FIG. 2, in the inactive state in which the power of the battery 260 is provided to the control circuitry 230, the IR sensor 240, and/or the control circuit (e.g., MCU) 250, an electric connection between the control circuitry 230 and the power circuitry 210 may be blocked by the diode 232. Since the power circuitry 210 is deactivated in the inactive state, potential (e.g., a voltage of the anode of the diode 232) of the power circuitry 210 may be lower than potential (e.g., a voltage of the cathode of the diode 232) of the control circuitry 230 receiving the power of the battery 260. Since the voltage of the anode of the diode 232 is lower than the voltage of the cathode of the diode 232, the diode 232 may be electrically insulated in the inactive state.

Referring to FIG. 2, the display device 101 may detect a user input to switch the display device 101 from the inactive state to the active state in the inactive state. In order to detect the user input, the IR sensor 240, the control circuitry 230, and/or the control circuit (e.g., MCU) 250 may be activated in the display device 101.

For example, when receiving a signal indicating the user input, the IR sensor 240 may notify the MCU 250 of reception of the signal. Based on notification of the IR sensor 240, the MCU 250 may switch a state of the display device 101 to the active state. When switching from the inactive state to the active state, the MCU 250 may control the power circuitry 210 so that the power circuitry 210 outputs one or more direct current signals. For example, based on receiving the signal, the MCU 250 may control the power circuitry 210 to start driving of the electronic component of the display device 101 including the display panel. After the one or more direct current signals are output from the power circuitry 210, the electronic component and/or the heat generating element of the display device 101 may be activated by the power circuitry 210. When switching from the inactive state to the active state, the MCU 250 may control the switch 234 to electrically insulate the battery 260 from the electronic component (e.g., the MCU 250 and/or the IR sensor 240) of the display device 101.

Although an embodiment providing the power to the IR sensor 240 using the battery 260 in the inactive state has been described, the disclosure is not limited thereto. The MCU 250 may measure a state of charge (SOC) and/or a battery cycle of the battery 260. While the power of the battery 260 is provided to the IR sensor 240 (e.g., during the inactive state), the MCU 250 may control the power circuitry 210, the switch 234, and/or the control circuitry 230 to obtain the power for driving of the IR sensor 240 from the power circuitry 210, in case that the SOC and/or a voltage (e.g., an open circuit voltage (OCV)) of the battery 260 is reduced to less than a preset SOC and/or a preset voltage.

As described above, according to an embodiment, the MCU 250 and/or the control circuitry 230 of the display device 101 may control the power circuitry 210 to reduce the standby power of the display device 101 measured from the power system 110. For example, in response to an input to switch the display device 101 to the inactive state, the MCU 250 and/or the control circuitry 230 may control the power circuitry 210 to reduce the standby power. In the inactive state, in order to support control of the display device 101 by an external electronic device such as the remote controller 109 illustrated in FIG. 1, communication circuitry (e.g., the IR sensor 240 and/or communication circuitry based on a wireless communication protocol such as Bluetooth) to the external electronic device may be activated. The communication circuitry and a controller (e.g., the MCU 250) connected to the communication circuitry may be activated by the battery 260 charged in the active state.

Since the battery 260 is charged based on the thermoelectric element 280, an additional circuitry to charge the battery 260 using the alternate current signal received from the power system 110 may not be included in the display device 101. For example, the display device 101 may be produced or implemented without circuitry for converting the alternate current signal into the direct current signal or charging the battery 260 using the converted direct current signal. For example, since the display device 101 is implemented without additional rectifier circuitry for charging the battery 260, transformer, and/or protection circuitry (e.g., circuitry to protect the battery 260 from lightning), the display device 101 may be implemented by adding relatively few electronic circuitry (e.g., the battery 260, the charging circuitry 270, and/or the thermoelectric element 280) while having reduced standby power.

Hereinafter, referring to FIG. 3, the thermoelectric element 280 included in the display device 101 to charge the battery 260 will be described in greater detail.

FIG. 3 is a diagram including a cross-sectional view illustrating a plurality of thermoelectric elements (e.g., the thermoelectric element 280 of FIG. 2) included in a display device (e.g., the display device 101 of FIGS. 1 to 2) according to various embodiments. Referring to FIG. 3, an array of the thermoelectric elements including a thermoelectric element 330 is illustrated. For example, and without limitation, the array of the thermoelectric elements may have a linear shape along a length direction of a heat generating element. For example, the array of the thermoelectric elements may have a planar shape on a surface of the heat generating element.

Referring to FIG. 3, the thermoelectric element 330 may include a first electrode 341, a second electrode 342, a third electrode 343, an n-doped semiconductor 350, and a p-doped semiconductor 360. A first surface of the n-doped semiconductor 350 may be contacted with a first portion of the first electrode 341. A second surface of the n-doped semiconductor 350 opposite to the first surface may be contacted with the second electrode 342. A first surface of the p-doped semiconductor 360 may be contacted (e.g., be in contact) with a second portion (e.g., a second portion spaced apart from the first portion of the first electrode 341 to which the n-doped semiconductor 350 is contacted, and located on the same surface as the first portion) of the first electrode 341. A second surface of the p-doped semiconductor 360 opposite to the first surface of the p-doped semiconductor 360 may be contacted with the third electrode 343. The first electrode 341, the second electrode 342, and the third electrode 343 may include a conductive material such as a metal (e.g., copper).

For example, the n-doped semiconductor 350 is a semiconductor doped with a group 5 element (e.g., (P), arsenic (As), and/or antimony (Sb)), and free electrons may be moved in the n-doped semiconductor 350. For example, the p-doped semiconductor 360 is a semiconductor doped with a group 3 element (e.g., boron (B), and/or aluminum (Al)), and movement of electrons in the p-doped semiconductor 360 may be described based on movement of electron holes (or a positive hole). A temperature distribution of the n-doped semiconductor 350 and the p-doped semiconductor 360 may cause movement of the free electrons and electron holes of each of the n-doped semiconductor 350 and the p-doped pe semiconductor 360.

For example, in the p-doped semiconductor 360, electron holes may be moved from a relatively high-temperature portion of the p-doped semiconductor 360 to another relatively low-temperature portion. For example, in the n-doped semiconductor 350, electrons may be moved from a relatively high-temperature portion of the n-doped semiconductor 350 to another relatively low-temperature portion. Referring to FIG. 3, in a case in which a temperature of the first electrode 341 is higher than a temperature of the second electrode 342 and the third electrode 343, electron holes of the p-doped semiconductor 360 may be moved toward the third electrode 343, and the free electrons of the n-doped semiconductor 350 may be moved toward the second electrode 342. In the case, a portion of the p-doped semiconductor 360 adjacent to the first electrode 341 may be negatively charged, and another portion of the p-doped semiconductor 360 adjacent to the third electrode 343 may be positively charged. In the case, a portion of the n-doped semiconductor 350 adjacent to the first electrode 341 may be positively charged, and another portion of the n-doped semiconductor 350 adjacent to the second electrode 342 may be negatively charged. A phenomenon in which the p-doped semiconductor 360 and the n-doped semiconductor 350 are charged may be described by a Seebeck effect.

In the case in which the temperature of the first electrode 341 is higher than the temperature of the second electrode 342 and the third electrode 343, potential differences based on the distributions of free electrons and electron holes may occur in each of the n-doped semiconductor 350 and the p-doped semiconductor 360. For example, since the free electrons of the n-doped semiconductor 350 are moved toward the second electrode 342, potential of the second electrode 342 may be reduced to less than potential of the first electrode 341. For example, since the positive holes of the p-doped semiconductor 360 are moved toward the third electrode 343, potential of the third electrode 343 may be increased beyond the potential of the first electrode 341. Since the potential difference occurs, a current may flow between the third electrode 343 and the second electrode 342. Based on the movement of the free electrons and electron holes, heat may be moved in the thermoelectric element 330. For example, the heat of the first electrode 341 may be moved to the second electrode 342 and/or the third electrode 343 along the n-doped semiconductor 350 and/or the p-doped semiconductor 360.

Referring to FIG. 3, the thermoelectric element 330 may be connected with the p-doped semiconductor of another thermoelectric element through the second electrode 342, and may be connected to the n-doped semiconductor of another thermoelectric element through the third electrode 343. In a plurality of thermoelectric elements including the thermoelectric element 330, the n-doped semiconductor and the p-doped semiconductor may be arranged to be alternately connected. In case that a plurality of n-doped semiconductors and p-doped semiconductors of the thermoelectric element 330 are alternately connected, the current may flow from a first n-doped semiconductor to a first p-doped semiconductor, from the first p-doped semiconductor to a second n-doped semiconductor, and from the second n-doped semiconductor to a second p-doped semiconductor again. For example, the n-doped semiconductor may be located next to the p-doped semiconductor. For example, between the p-doped semiconductors, the n-doped semiconductor may be located. When the plurality of thermoelectric elements is connected, a power signal having a combination of potential differences of the plurality of thermoelectric elements may be output.

As described above, in the thermoelectric element 330, a current flow and/or movement of heat based on a temperature difference between both ends of the n-doped semiconductor 350 (or the p-doped semiconductor 360) may occur. According to an embodiment, in the display device, the thermoelectric element 330 may be positioned so that both ends of a semiconductor (e.g., the n-doped semiconductor 350 and/or the p-doped semiconductor 360) included in the thermoelectric element 330 have the temperature difference. The temperature difference may be generated by heat emitted from the heat generating element of the display device.

Referring to FIG. 3, the thermoelectric element 330 may include a first plate 321. The thermoelectric element 330, and the plurality of thermoelectric elements including the thermoelectric element 330 may be contacted with the first plate 321. The first electrode 341 of the thermoelectric element 330 may be contacted with the first plate 321. A surface 311 opposite to a surface of the first plate 321 with which the first electrode 341 is contacted may be contacted with or may be attached to the heat generating element of the display device.

Referring to FIG. 3, the thermoelectric element 330 may include a second plate 322. The thermoelectric element 330, and the plurality of thermoelectric elements including the thermoelectric element 330 may be contacted with the second plate 322. The second electrode 342 and the third electrode 343 of the thermoelectric element 330 may be contacted with or attached to the second plate 322. A surface 312 opposite to a surface of the second plate 322 with which the second electrode 342 and/or the third electrode 343 are contacted may be contacted with or attached to a heat dissipation element of the display device. Since the surface 311 of the thermoelectric element 330 is contacted with the heat generating element and the surface 312 opposite to the surface 311 is contacted with the heat dissipation element, heat of the heat generating element may be moved to the heat dissipation element through the thermoelectric element 330. Movement of the heat may cause generation of an electromotive force based on a temperature difference between the surfaces 311 and 312.

Referring to FIG. 3, the thermoelectric element 330 may be interposed or located between the first plate 321 and the second plate 322. Through the surface 311 of the first plate 321, the thermoelectric element 330 may be contacted with the heat generating element. The thermoelectric element 330 may be contacted with the heat dissipation element through the surface 312 of the second plate 322. The n-doped semiconductor 350 may extend from another surface of the first plate 321 opposite to the surface 311 of the first plate 321 attached to the heat generating element, toward the surface 312 of the second plate 322. The p-doped semiconductor 360 may extend from another portion spaced apart from a portion to which the n-doped semiconductor 350 is attached, on the surface of the first plate 321, toward the surface 312 of the second plate 322. The disclosure is not limited thereto, and the heat generating element may be attached to the thermoelectric element 330 through the surface 312 of the second plate 322, and the heat dissipation element may be attached to the thermoelectric element 330 through the surface 311 of the first plate 321.

As described above, the thermoelectric element 330 may be configured to generate power based on the temperature difference generated in the display device. Thermoelectric elements including the thermoelectric element 330 may be connected in series. Based on a series connection of thermoelectric elements, the power may be generated more efficiently. In order to maintain or make the temperature difference, the heat generating element, the thermoelectric element 330, and the heat dissipation element may be sequentially connected in the display device. The heat dissipation element may be configured to emit the heat moved from the thermoelectric element 330 to an outside of the heat dissipation element. The heat dissipation element may include a chassis (e.g., a bottom chassis), a frame, and/or a housing of the display device.

As described above, the thermoelectric element 330 of the display device may generate the power based on the temperature difference between the first temperature of the surface 311 based on the heat emitted from the heat generating element, and the second temperature of the surface 312 lower than the first temperature by the heat dissipation element. In case that the thermoelectric element 330 is electrically coupled with the battery (e.g., the battery 260 of FIG. 2), the thermoelectric element 330 may be configured to charge the battery. The disclosure is not limited thereto, and when the surface 311 is attached to the heat dissipation element and the surface 312 is attached to the heat generating element, a temperature of the surface 311 may be lower than a temperature of the surface 312. The thermoelectric element 330 may generate the power based on the temperature difference between the surfaces 311 and 312. The battery may be charged by the generated power.

Hereinafter, an example structure of the display device including the thermoelectric element 330, the heat generating element, and the heat dissipation element will be illustrated and described in greater detail with reference to FIG. 4.

FIG. 4 is an exploded perspective view of a display device 101 according to various embodiments. An example non-limiting structure of the display device 101 of FIG. 1 and/or FIG. 2 will be described with reference to FIG. 4.

Referring to FIG. 4, the display device 101 may include a display panel 410. A front surface (e.g., a front side) of the display device 101 may be described as a surface of the display device 101 which is visible by the display panel 410. A rear surface (e.g., a rear side) of the display device 101 may be described as a surface (or another surface) of the display device 101 opposite to the front surface of the display device 101.

The display device 101 may include the display panel 410 and a housing 420 supporting the display panel 410. The housing 420 may include a rear cover of the display device 101. The housing 420 may include an object (e.g., a support leg and/or video electronics standards association (VESA) mount holes) to support the display device 101.

A chassis 417 may be located on another surface of the display panel 410 opposite to a surface of the display panel 410 facing the front surface of the display device 101. The chassis 417 may be referred to as a bottom chassis of the display panel 410. On the chassis 417, a printed circuit board (PCB) in which one or more circuit elements (e.g., SoC) are positioned may be coupled. Referring to FIG. 4, a first PCB in which power circuitry 210 is positioned may be located on the chassis 417. In terms of including the power circuitry 210, the first PCB may be referred to as a power board. Referring to FIG. 4, a second PCB in which control circuitry 430 (e.g., the control circuitry 230 of FIG. 2) distinct from the power circuitry 210 is positioned may be located on the chassis 417. In terms of including the control circuitry 430, the second PCB may be referred to as a control board, a main board, and/or a logic board.

Referring to FIG. 4, an exploded perspective view of the display panel 410 is illustrated. The display panel 410 may include a liquid crystal panel 411, a backlight component (or a backlight unit, a backlight module including light emitting circuitry, e.g., LEDs) that emits light (e.g., white light) to the liquid crystal panel 411, and a chassis assembly that supports the liquid crystal panel 411 and the backlight unit. The backlight component may include at least one of a light source component 440, a light guide plate 415 that generates a surface light source from light of the light source component 440, a reflective sheet 416 positioned toward another surface opposite to a surface of the light guide plate 415 facing the liquid crystal panel 411, a quantum dot sheet 414 that is located between the liquid crystal panel 411 and the light guide plate 415 and is configured to change (e.g., to enhance color reproducibility) a wavelength of light reflected by the light guide plate 415, and an optical sheet 412 that is located between the quantum dot sheet 414 and the liquid crystal panel 411, and is configured to change luminance, uniformity, and directivity of light.

Referring to FIG. 4, the light source component 440 may be positioned along any one periphery of the display panel 410 (e.g., an underground backlight component and/or an edge backlight component). The disclosure is not limited thereto, and the light source component 440 may have a shape of the surface light source on the rear surface of the display panel 410. The light source component 440 may include a plurality of LEDs and a PCB in which the plurality of LEDs is located.

The chassis assembly of the display panel may be configured to accommodate the liquid crystal panel 411 and the backlight component. The chassis assembly may include a middle mold 413 and the chassis 417. Although not illustrated, the chassis assembly may include a bezel component that is visible from the front surface of the display device 101. The chassis 417 may have a structure to accommodate PCBs including the power circuitry 210 and the control circuitry 430. An example appearance of the chassis 417, the power circuitry 210, and the control circuitry 430 will be described in greater detail below with reference to FIGS. 7A, 7B and 7C. The chassis 417 may include aluminum, stainless steel (SUS), and/or stainless steel electrogalvanized cold-rolled steel (SECC) with relatively high heat conductivity.

The power circuitry 210 and/or the control circuitry 430 may be located on the chassis 417 configured to support the display panel 410. The chassis 417 may be positioned on the surface of the display panel 410 and may include a heat dissipation portion adjacent to a heat generating element. The chassis 417 may include a support portion (e.g., a bracket) supporting the PCB (e.g., the first PCB in which the power circuitry 210 is located and/or the second PCB in which the control circuitry 430 is located). In an embodiment, heat of the heat generating element included in the power circuitry 210 and/or the control circuitry 430 may be moved to the chassis 417. Power may be generated from a thermoelectric element (e.g., the thermoelectric element 280 of FIG. 2) located (or interposed) between the heat generating element and the chassis 417. For example, the control circuitry 430 may include the heat generating element (e.g., SoC) that is coupled on the second PCB in which the control circuitry 430 is located and configured to emit the heat based on driving of the display panel 410.

For example, the heat generating element may include the power circuitry 210 configured to obtain power for driving of the display device 101 from an external power system (e.g., the power system 110 of FIG. 1) of the display device 101. The display panel 410 may be driven by the power obtained by the power circuitry 210. The thermoelectric element may include a first surface (e.g., the surface 311 of FIG. 3) attached on a surface formed on at least a portion of the power circuitry 210, and a second surface (e.g., the surface 312 of FIG. 3) attached to the chassis 417 opposite to the first surface. The thermoelectric element may be configured to at least partially convert heat energy of at least one of the power circuitry 210 and/or the control circuitry 430 into electric energy. The electric energy may be stored in a battery (e.g., the battery 260 of FIG. 2) of the display device 101.

For example, the heat generating element may include backlight LEDs configured to emit light toward the display panel 410 (or the liquid crystal panel 411). The backlight LEDs may be included in the light source component 440. The first surface of the thermoelectric element may be at least partially attached to the backlight LEDs which are arranged along a length direction of the display panel 410. The second surface of the thermoelectric element opposite to the first surface may be attached to the chassis 417.

As described above with reference to FIGS. 1, 2 and 3, the display device 101 may include an electronic component (e.g., the IR sensor 240 and/or the MCU 250 of FIG. 2) configured to be at least partially driven by the power charged in the battery (e.g., the battery 260 of FIG. 2), based on electric isolation between the power system and the display device 101. The electronic component may include the IR sensor (e.g., the IR sensor 240 of FIG. 2). The electronic component may include a controller (e.g., the MCU 250 and/or the control circuitry 230 of FIG. 2) configured to control the IR sensor.

As described above, the chassis 417 formed widely on the rear surface of the display panel 410 may be described as a heat dissipation element to receive heat from the heat generating element. Since the chassis 417 has a relatively large area, heat transmitted to the chassis 417 may be diffused on the chassis 417. The thermoelectric element may be located between the heat generating element and the heat dissipation element. Based on a temperature difference between the heat generating element and the heat dissipation element, the thermoelectric element may output power.

Hereinafter, various example locational relations between the heat generating element, the heat dissipation element, and the thermoelectric element will be illustrated in greater detail with reference to FIGS. 5A, 5B and 5C.

FIGS. 5A, 5B, and 5C are diagrams illustrating example coupling relationships between a thermoelectric element 280 and a heat generating element included in a display device according to various embodiments. The display device 101 of FIGS. 1, 2, 3 and 4 may include the thermoelectric element 280 and the heat generating element with the coupling relationship illustrated in FIGS. 5A, 5B and 5C (which may be referred to as FIGS. 5A to 5C).

Referring to FIGS. 5A to 5C, example structures of a PCB 520 and a chassis 510 are illustrated. The chassis 510 of FIGS. 5A to 5C may include the chassis 417 of FIG. 4. The chassis 510 may include a bracket to fix the PCB 520. The chassis 510 and the heat generating element may be connected (indirectly) or (at least partially) be contacted through a heat transfer object such as the thermoelectric element 280.

Referring to FIG. 5A, as an example of the heat generating element positioned on the PCB 520, electronic components 530 are illustrated. As an example of the electronic components 530, a first electronic component 531, a second electronic component 532, and a third electronic component 533 are illustrated, but the disclosure is not limited thereto. The electronic components 530 may be included in power circuitry (e.g., the power circuitry 210 of FIG. 2) of the display device.

Referring to FIG. 5A, the thermoelectric element 280 may include a first surface attached to the electronic components 530 and a second surface attached to the chassis 510. In an embodiment in which the electronic components 530 are included in the power circuitry, the first surface of the thermoelectric element 280 may be attached on at least a portion of the power circuitry. Due to a temperature difference between the first surface and the second surface, the thermoelectric element 280 may be configured to generate power. Dimensions (e.g., width, height, and/or thickness) of the thermoelectric element 280 may be set to at least partially occupy (or fill) a space between the electronic components 530 and the chassis 510. The thermoelectric element 280 may be located in the space without an additional insulator (e.g., an aluminum oxide (Al₂O₃) insulator). For example, the display device may be designed without the insulator, or the insulator of the display device may be replaced by the thermoelectric element 280.

Referring to FIG. 5A, in order to directly connect the thermoelectric element 280 and the electronic components 530, a penetration hole may be formed on the PCB 520. For example, the PCB 520 may include the penetration hole at least partially overlapped to the heat generating element (e.g., the electronic components 530) positioned on the PCB 520. The first surface of the thermoelectric element 280 may be contacted with the heat generating element through the penetration hole of the PCB 520. Referring to FIG. 5A, the penetration hole of the PCB 520 may be filled by contact between the thermoelectric element 280 and the heat generating element.

As described above with reference to FIG. 5A, since heat generated in the electronic components 530 moves to the chassis 510 through the thermoelectric element 280, the display device may be designed or produced without an additional component (e.g., a heat sink, and/or the insulator) to emit the heat from the electronic components 530. The disclosure is not limited thereto, and since the heat generated in the electronic components 530 moves to the chassis 510 through the thermoelectric element 280, the display device may be configured to include the heat sink having a reduced size.

Referring to FIG. 5A, the electronic components 530 may be dispersed on the surface of the thermoelectric element 280. Referring to FIG. 5A, a first thermal image 591 of the surface of the thermoelectric element 280 contacted with the electronic components 530 is illustrated. A portion 593 of the first thermal image 591 may correspond to the surface of the thermoelectric element 280 with which the electronic components 530 are contacted. Referring to the first thermal image 591, in the portion 593, a temperature of the portion overlapped to the electronic components 530 or adjacent to the electronic components 530 may be higher than a temperature of the remaining portion. Referring to FIG. 5B, in order to uniformly transfer the heat to the surface of the thermoelectric element 280, a metal plate 540 may be located between the thermoelectric element 280 and the heat generating element (e.g., the electronic components 530). For example, referring to FIG. 5B, the PCB 520 may include a first portion on which the heat generating element (e.g., the electronic components 530) is mounted and a second portion surrounding the first portion. The first portion may include the metal plate 540.

The metal plate 540 may be referred to as a metal PCB (or a metal). The heat of the electronic components 530 may diffused on the metal plate 540. When the heat is uniformly received through the metal plate 540, the thermoelectric element 280 may generate or output power more efficiently. Referring to FIG. 5B, a second thermal image 592 of the surface of the thermoelectric element 280 with which the electronic components 530 are contacted is illustrated. A portion 594 of the second thermal image 592 may correspond to the surface of the thermoelectric element 280 with which the electronic components 530 are contacted. Referring to the second thermal image 592, in the portion 594, a deviation between a temperature of the portion in which the electronic components 530 are positioned and a temperature of the remaining portion may be reduced. For example, the deviation in the portion 594 of the second thermal image 592 of FIG. 5B may be smaller than the deviation in the portion 593 of the first thermal image 591 of FIG. 5A. As the deviation is smaller, magnitude of a current generated by the thermoelectric element 280 may be increased. For example, as a temperature deviation on the surface of the thermoelectric element 280 is decreased, using the metal plate 540, the temperature of the electronic components 530 may be decreased and the magnitude of the current generated from the thermoelectric element 280 may also be increased.

Referring to FIG. 5C, the heat generating element positioned on the PCB 520 may include an SoC 550. The SoC 550 may be included in circuitry for driving of the display panel, such as the control circuitry 430 of FIG. 4 and the control circuitry 230 of FIG. 2. The display device may include a heat sink 560 to emit heat from the SoC 550. The heat sink 560 may be attached to or connected to a heat dissipation element (e.g., the chassis 510 and/or a housing) of the display device. For example, an end of the heat sink 560 may be contacted with or may be connected to another surface of the thermoelectric element 280 opposite to the surface (e.g., the surface of the thermoelectric element 280 that is contacted with a surface of the SoC 550) of the thermoelectric element 280. For example, another end distinct from the end of the heat sink 560 may be contacted with or connected to the heat dissipation element of the display device such as the chassis and/or the housing.

Referring to FIG. 5C, the thermoelectric element 280 may be interposed between the SoC 550 and the heat sink 560. For example, the SoC 550 in an active state may emit heat when controlling the display panel to output an image and/or controlling one or more speakers to output sound. The heat may be moved from the surface of the thermoelectric element 280 to another surface of the thermoelectric element 280. The heat moved to the another surface of the thermoelectric element 280 may be transmitted to the heat sink 560. When the heat is moved from the surface of the thermoelectric element 280 to the another surface of the thermoelectric element 280, a current flow (e.g., movement of electrons) may occur in the thermoelectric element 280. The current generated by the thermoelectric element 280 may flow to a battery connected to both ends of the thermoelectric element 280. For example, the battery may be charged by the current generated by the thermoelectric element 280.

FIGS. 6A, 6B, and 6C are diagrams illustrating an example coupling relationship between a coil assembly and a heat generating element included in a display device according to various embodiments. The display device 101 of FIGS. 1 to 4 may include hardware illustrated in FIGS. 6A, 6B, and/or 6C.

FIG. 6A is an example circuit diagram of the power circuitry 210, the LED driving circuitry 220, and the control circuitry 230 of FIG. 2. The power circuitry 210 may include rectifier circuitry 212 to rectify an alternate current signal of a power system 110, and alternate current-direct current conversion circuitry 214 that generates a direct current signal from the alternate current signal rectified by the rectifier circuitry 212. Referring to FIG. 6A, a power factor corrector (PFC) may be connected to the alternate current-direct current conversion circuitry 214, or may be included as at least a portion of the alternate current-direct current conversion circuitry 214. Referring to FIG. 6A, the power circuitry 210 may include direct current-direct current conversion circuitry 216 to output direct current signals with distinct voltages required for driving of distinct electronic components of the display device from the direct current signal of the alternate current-direct current conversion circuitry 214.

Referring to FIG. 6A, the direct current-direct current conversion circuitry 216 may include circuitry to convert the direct current signal of the alternate current-direct current conversion circuitry 214 into the alternate current signal. The circuitry may include, for example, a resonator (or resonance circuitry) based on an inductor-inductor-capacitor (LLC). The direct current-direct current conversion circuitry 216 may include a primary coil that receives the alternate current signal converted from the direct current signal of the alternate current-direct current conversion circuitry 214, and one or more secondary coils inductively coupled with the primary coil. Referring to FIG. 6A, a portion 610 of the direct current-direct current conversion circuitry 216 the primary coil and a plurality of secondary coils are combined is illustrated. Although the portion 610, in which two secondary coils are inductively coupled with the primary coil, is illustrated, the disclosure is not limited thereto. Each of the secondary coils of the portion 610 may be connected with the alternate current-direct current conversion circuitry (e.g., a capacitor-based smoothing circuitry). The direct current signal to drive a corresponding electronic component (e.g., the LED driving circuitry 220, the display panel 410, and/or the control circuitry 230) may be output from the alternate current-direct current conversion circuitry connected to the secondary coil.

Referring to FIG. 6A, examples (e.g., a first coil assembly 621 and/or a second coil assembly 622) of the coil assembly in which the primary coil and the secondary coils included in the portion 610 are engaged with each other are illustrated. The coil assembly may be referred to as a transformer. In the coil assembly, the primary coil and the secondary coils may be electrically insulated from each other. FIG. 6B illustrates the first coil assembly 621 of FIG. 6A and a first thermoelectric element 280-1 which is contacted on a surface of the first coil assembly 621. FIG. 6C illustrates the second coil assembly 622 and a second thermoelectric element 280-2 which is contacted on a surface of the second coil assembly 622.

Referring to FIG. 6B, the first coil assembly 621 positioned on a PCB 630 is illustrated. In the first coil assembly 621, a plurality of coils (e.g., the coils included in the portion 610 of FIG. 6A) may be coupled to each other. A ferrite core, associated with mutual coupling of the plurality of coils, may be included in the first coil assembly 621. The PCB 630 in which the first coil assembly 621 is positioned may include a penetration hole at least partially overlapped to the first coil assembly 621. Through the penetration hole, the surface of the first coil assembly 621 and a surface of the first thermoelectric element 280-1 may be contacted with each other.

Referring to FIG. 6C, the second coil assembly 622 may include circuit elements 641 and 642 such as a FET and/or diode. The circuit elements 641 and 642 may be positioned on a surface of the second coil assembly 622. In the second coil assembly 622, the plurality of coils may be mutually coupled. The second coil assembly 622 may further include at least one core located between the plurality of coils. The second coil assembly 622 may be positioned on the PCB 630. The PCB 630 may include a penetration hole at least partially overlapped to the surface (e.g., the surface of the second coil assembly 622 where the circuit elements 641 and 642 are located) of the second coil assembly 622. Through the penetration hole, the surface of the second coil assembly 622 and a surface of the second thermoelectric element 280-2 may be contacted with each other.

Referring to FIGS. 6B and/or 6C, heat generated in the first coil assembly 621 and the second coil assembly 622 may be transmitted to the first thermoelectric element 280-1 and the second thermoelectric element 280-2, respectively. Based on the heat transmitted from each of the first coil assembly 621 and the second coil assembly 622, power may be generated from each of the first thermoelectric element 280-1 and the second thermoelectric element 280-2. The power may be charged by a battery (e.g., the battery 260 of FIG. 2). As described above, a thermoelectric element such as the first thermoelectric element 280-1 and the second thermoelectric element 280-2 may be configured to convert the heat emitted from a coil assembly (or a magnetic material) such as the first coil assembly 621 and the second coil assembly 622 into electric energy.

As described above with reference to FIGS. 5A, 5B, 5C, 6A, 6B, and/or 6C, the thermoelectric element may be located in the display device to receive heat from various heat generating elements (e.g., the electronic components 530 of FIGS. 5A to 5B, the SoC 550 of FIG. 5C, and/or the coil assembly 620 of FIGS. 6A to 6C) of the display device. Hereinafter, example locational relationships of the heat generating element, the thermoelectric element, and the heat dissipation element included in the display device will be illustrated with reference to FIGS. 7A to 7C.

FIGS. 7A, 7B, and 7C are diagrams illustrating example locational relationships of a thermoelectric element 280 and a battery element 710 included in a display device 101 according to various embodiments. Example locational relationships of the thermoelectric element, the battery, and the heat dissipation element included in the display device 101 of FIGS. 1, 2, 3 and 4 will be described with reference to FIGS. 7A, 7B and 7C (which may be referred to as FIGS. 7A to 7C).

Referring to FIGS. 7A to 7C, a chassis 417 of a display panel and the heat generating elements (e.g., control circuitry 430, and/or power circuitry 210) positioned on the chassis 470, viewed from a rear surface of the display device 101, are illustrated. Under a housing (or a rear cover) of the display device 101, the chassis 417 and the heat generating elements may be located to have a locational relationship (or layout) of any one of FIGS. 7A to 7C.

Referring to FIG. 7A, the thermoelectric element 280 may be contacted with at least a portion of the power circuitry 210. For example, a surface of the thermoelectric element 280 may be contacted with at least a portion (e.g., at least one of the coil assembly 620 described with reference to FIGS. 6A, 6B, or 6C, and/or the electronic components 530 of FIGS. 5A to 5B) of the power circuitry 210, and another surface of the thermoelectric element 280 may be contacted with the chassis 417. Power may be generated from the thermoelectric element 280 based on a temperature difference between both surfaces of the thermoelectric element 280.

Referring to FIG. 7A, the display device 101 may include the battery element 710. The battery element 710 may include the battery 260 and/or the charging circuitry 270 of FIG. 2. The battery element 710 may be mounted on or attached to the chassis 417. The battery element 710 may be connected with electrodes of the thermoelectric element 280. Through the electrodes, a battery of the battery element 710 may be charged by the thermoelectric element 280. To assist the charging, the battery element 710 may further include the charging circuitry (e.g., the charging circuitry 270 of FIG. 2). Although an embodiment in which the battery element 710 is located on a lateral surface of the display device 101 is illustrated, the disclosure is not limited thereto.

Referring to FIG. 7B, the thermoelectric element 280 may be contacted with a light source element 440 of a backlight component of the display panel. The thermoelectric element 280 may have a shape corresponding to a shape of the light source element 440. The surface of the thermoelectric element 280 may be contacted with the light source element 440, and the another surface of the thermoelectric element 280 may be contacted with the chassis 417. The thermoelectric element 280 may output or generate power based on heat generated by the light source element 440.

Referring to FIG. 7B, the battery element 710 of the display device 101 may be included in an accessory (e.g., a stand member) of the display device 101. For example, the battery element 710 may be included as a module in the stand member of the display device 101. For example, when the display device 101 and the stand member are fastened (or connected), an electric connection between the battery element 710 and the thermoelectric element 280 may be established or formed.

Referring to FIG. 7C, the display device 101 may include a plurality of thermoelectric elements (e.g., a first thermoelectric element 281 and a second thermoelectric element 282). The first thermoelectric element 281 may be contacted on at least a portion of the power circuitry 210. The second thermoelectric element 282 may be contacted on another heat generating element of the display device 101, such as the light source element 440. When the battery element 710 is charged by a plurality of thermoelectric elements such as the first thermoelectric element 281 and the second thermoelectric element 282, the battery element 710 may be connected to the plurality of thermoelectric elements in series.

Referring to FIG. 7C, an example circuit diagram of the plurality of thermoelectric elements and the battery element 710 is illustrated. The first thermoelectric element 281, the second thermoelectric element 282, and the battery element 710 may be connected in series. For example, a first electrode of the battery element 710 and an anode of the first thermoelectric element 281 may be connected, a cathode of the first thermoelectric element 281 may be connected with an anode of the second thermoelectric element 282, and a cathode of the second thermoelectric element 282 may be connected with a second electrode of the battery element 710. In an embodiment in which the plurality of thermoelectric elements is connected in series, the battery element 710 (or the charging circuitry 270 included in the battery element 710) may receive a power signal having a composite voltage of the plurality of thermoelectric elements. The battery element 710 may be charged by the power signal.

Although a series connection of thermoelectric elements located on the light source element 440 and the power circuitry 210 is illustrated by way of example, the disclosure is not limited thereto. For example, the thermoelectric element may be additionally located on the SoC (e.g., the SoC 550 of FIG. 5C) of the control circuitry 430. In this case, a series connection between the first thermoelectric element 281, the second thermoelectric element 282, and the thermoelectric element located on the SoC may be established. Through the series connection, the battery element 710 may receive power based on heat generated from the heat generating element of the display device 101.

As described above, according to an embodiment, the display device 101 may be configured to convert electric energy from heat of the heat generating element included in the display device 101 and store the converted electric energy. The stored electric energy may be used during an inactive state of the display device 101 to reduce standby power. In order to reduce the standby power, the display device 101 may be electrically isolated from the power system when using the electric energy. The electric energy may be used to detect an input to switch a state of the display device 101 from the inactive state to an active state.

In an embodiment, a method of minimizing and/or reducing the standby power of the display device 101 may be required. In an embodiment, a method of reducing the number of components included in the display device 101 may be required. In an embodiment, a method of reducing volume of the display device 101 may be required. In an embodiment, a method of reducing a thickness (or depth) of the display device 101 may be required. In an embodiment, a method of reducing an element for heat dissipation (or heat emitting) included in the display device 101 may be required. In an embodiment, a method of recycling heat generated from the heat generating element of the display device 101 may be required.

As described above, according to an example embodiment, a display device (e.g., the display device 101 of FIG. 1) may comprise: a display panel (e.g., the display panel 410 of FIG. 4), a printed circuit board (PCB) (e.g., the PCB 520 of FIG. 5A to FIG. 5C), a heat generating element comprising an electronic component including various circuitry coupled on the PCB and configured to emit heat based on driving of the display panel, a chassis (e.g., the chassis 417 of FIG. 4), positioned on a surface of the display panel, including a heat dissipation portion comprising a thermally conductive material adjacent to the heat generating element, and a support portion configured to support the PCB, a thermoelectric element comprising at least one electrode (e.g., the thermoelectric element 280 of FIG. 2), interposed between the heat generating element and the heat dissipation portion, including a first surface in contact with the heat generating element and a second surface in contact with the heat dissipation portion, and a battery (e.g., the battery 260 of FIG. 2) connected to the thermoelectric element. The thermoelectric element may be configured to charge the battery based on a temperature difference between a first temperature of the first surface, associated with the heat emitted from the heat generating element, and a second temperature of the second surface, which is lower than the first temperature by the heat dissipation portion.

For example, the heat generating element may comprise: a coil assembly comprising at least one coil (e.g., the coils of FIG. 6A) engaged to each other to be mutually coupled to each other, and diodes (e.g., the diodes of FIG. 6A) respectively connected to distinct ends of the coils. The first surface of the thermoelectric element may be attached on a surface of the coil assembly where the diodes are positioned.

For example, the PCB may comprise a penetration hole at least partially overlapping the heat generating element positioned on the PCB. The first surface of the thermoelectric element may in contact with the heat generating element through the penetration hole of the PCB.

For example, the heat generating element may comprise backlight light emitting diodes (LEDs) configured to emit light toward the display panel. The first surface of the thermoelectric element may be at least partially attached to the backlight LEDs which are arranged along a length direction of the display panel.

For example, the display device may comprise a system on a chip (SoC) (e.g., the SoC 550 of FIG. 5C) including various circuitry configured to drive of the display panel, a heat sink (e.g., the heat sink 560 of FIG. 5B), and another thermoelectric element comprising at least one electrode and having a third surface attached to the SoC and a fourth surface attached to the heat sink. The battery may be coupled in series with the thermoelectric element, and the another thermoelectric element.

For example, the PCB may comprise a first portion where the heat generating element is mounted, and a second portion surrounding the first portion. The first portion may comprise a metal (e.g., the metal plate 540 of FIG. 5B).

For example, the display device may comprise charging circuitry (e.g., the charging circuitry 270 of FIG. 2) configured to control charging of the battery based on power generated by the thermoelectric element. The charging circuitry may be configured to adjust an electric current input to the battery to maintain generation of the power by the thermoelectric element.

For example, the thermoelectric element may comprise a plate (e.g., the first plate 321 of FIG. 3) including the first surface (e.g., the surface 311 of FIG. 3) attached to the heat generating element, a n-doped semiconductor (e.g., the n-doped semiconductor 350 of FIG. 3) extending from a first portion on a third surface of the plate opposite to the first surface, toward the second surface, and a p-doped semiconductor (e.g., the p-doped semiconductor 360 of FIG. 3) extending from a second portion on the third surface spaced apart from the first portion on the third surface of the plate, to the second surface.

As described above, according to an example embodiment, a display device may comprise: a controller comprising circuitry, power circuitry configured to obtain electric power from a power system outside of the display device and configured to drive of the display device, an infrared (IR) sensor, a display panel, a thermoelectric element including at least one electrode configured to at least partially convert heat energy of at least one of the controller or the power circuitry into electric energy, and a battery configured to store the electric energy. The controller may be configured to: receive a first input to cease provision of an image through the display panel. The controller may be configured to, based on the first input, deactivate the display panel and the power circuitry. The controller may be configured to, based on the deactivation, activate the IR sensor using the electric energy stored in the battery to detect a second input to start provision of an image through the display panel through the IR sensor.

For example, the display device may comprise a chassis configured to support the display panel. The thermoelectric element may comprise a first surface attached on at least a portion of the power circuitry and a second surface attached to the chassis.

For example, the controller may be configured to, based on receiving the input, control the power circuitry to reduce standby power of the display device that is estimated by the power system.

For example, the controller may be configured to, in response to detecting a signal indicating the second input through the IR sensor, control the power circuitry to start driving of the display panel based on power of the power system.

For example, the power circuitry may comprise a coil assembly comprising coils engaged to each other to be mutually coupled to each other and diodes connected to distinct ends of the coils. A surface of the thermoelectric element may be attached on a surface of the coil assembly where the diodes are positioned.

As described above, in an example embodiment, a method of controlling or operating a display device may be provided. The display device may comprise power circuitry configured to obtain power for driving of the display device from a power system of an outside of the display device, an infrared (IR) sensor, a display panel, a thermoelectric element including at least one electrode configured to at least partially convert heat energy of at least one of the power circuitry to electric energy, and a battery configured to store the electric energy. The method may comprise receiving a first input to cease provision of an image through the display panel. The method may comprise, based on the first input, deactivating the power circuitry and the display panel. The method may comprise, based on the deactivation, activating the IR sensor using the electric energy stored in the battery to detect, through the IR sensor, a second input to start provision of an image through the display panel.

As used herein, the term “if” is, optionally, understood to refer, for example, to “when” or “upon” or “in response to determining” or “in response to detecting,” depending on the context. Similarly, the phrase “if it is determined” or “if [a stated condition or event] is detected” is, optionally, understood to refer, for example, to “upon determining” or “in response to determining” or “upon detecting [the stated condition or event]” or “in response to detecting [the stated condition or event],” depending on the context.

The device described above may be implemented as a hardware component, a software component, and/or a combination of a hardware component and a software component. For example, the devices and components described in the disclosure may be implemented using one or more general purpose computers or special purpose computers, such as a processor, controller, arithmetic logic unit (ALU), digital signal processor, microcomputer, field programmable gate array (FPGA), programmable logic unit (PLU), microprocessor, or any other device capable of executing and responding to instructions. The processing device may perform an operating system (OS) and one or more software applications executed on the operating system. In addition, the processing device may access, store, manipulate, process, and generate data in response to the execution of the software. For convenience of understanding, there is a case that one processing device is described as being used, but a person who has ordinary knowledge in the relevant technical field may see that the processing device may include a plurality of processing elements and/or a plurality of types of processing elements. For example, the processing device may include a plurality of processors or one processor and one controller. In addition, another processing configuration, such as a parallel processor, is also possible.

The software may include a computer program, code, instruction, or a combination of one or more thereof, and may configure the processing device to operate as desired or may command the processing device independently or collectively. The software and/or data may be embodied in any type of machine, component, physical device, computer storage medium, or device, to be interpreted by the processing device or to provide commands or data to the processing device. The software may be distributed on network-connected computer systems and stored or executed in a distributed manner. The software and data may be stored in one or more computer-readable recording medium.

The method according to an example embodiment may be implemented in the form of a program command that may be performed through various computer means and recorded on a computer-readable medium. In this case, the medium may continuously store a program executable by the computer or may temporarily store the program for execution or download. In addition, the medium may be various recording means or storage means in the form of a single or a combination of several hardware, but the disclosure is not limited to a medium directly connected to a certain computer system, and may exist distributed on the network. Examples of media may include a magnetic medium such as a hard disk, floppy disk, and magnetic tape, optical recording medium such as a CD-ROM and DVD, magneto-optical medium, such as a floptical disk, and those configured to store program instructions, including ROM, RAM, flash memory, and the like. In addition, examples of other media may include recording media or storage media managed by app stores that distribute applications, sites that supply or distribute various software, servers, and the like.

As described above, although various example embodiments have been described with reference to the drawings, one skilled in the art will be capable of various modifications and alternatives from the above description. For example, even if the described technologies are performed in a different order from the described method, and/or the components of the described system, structure, device, circuit, and the like are coupled or combined in a different form from the described method, or replaced or substituted by other components or equivalents, appropriate a result may be achieved.

Therefore, other implementations, other embodiments, and deemed to be within the scope of the disclosure, including the appended claims are their equivalents. It will also be understood that any of the embodiment(s) described herein may be used in conjunction with any other embodiment(s) described herein.

What is claimed is:

1. A display device comprising:
a display panel;
a printed circuit board (PCB);
a heat generating element comprising an electronic component including various circuitry coupled on the PCB and configured to emit heat based on driving of the display panel;
a chassis, positioned on a surface of the display panel, including a heat dissipation portion comprising a thermally conductive material adjacent to the heat generating element, and a support portion configured to support the PCB;
a thermoelectric element comprising at least one electrode, interposed between the heat generating element and the heat dissipation portion, including a first surface in contact with the heat generating element and a second surface in contact with the heat dissipation portion; and
a battery connected to the thermoelectric element,
wherein the thermoelectric element is configured to charge the battery based on a temperature difference between a first temperature of the first surface, which is associated with the heat emitted from the heat generating element, and a second temperature of the second surface, which is lower than the first temperature by the heat dissipation portion.

2. The display device of claim 1, wherein the heat generating element comprises:
power circuitry configured to obtain power for driving of the display device from a power system of an outside of the display device,
wherein the thermoelectric element is attached on the first surface formed on at least a portion of the power circuitry.

3. The display device of claim 2, wherein the display panel is configured to be driven by the power obtained by the power circuitry,
wherein the display device further comprises:
an electronic component comprising various circuitry configured to be at least partially driven by power charged in the battery, based on electric isolation between the power system and the display device.

4. The display device of claim 3, wherein the display panel is configured to be deactivated by the electric isolation between the power system and the display device.

5. The display device of claim 3, wherein the electronic component comprises a controller comprising circuitry configured to:
in response to an input to cease provision of an image through the display panel:
control the power circuitry to start the electric isolation between the power system and the display device; and
establish an electric connection between the battery and at least a portion of the electronic component.

6. The display device of claim 5, wherein the electronic component comprises:
an infrared (IR) sensor;
wherein the controller is configured to establish, in response to the input, an electric connection between the battery and the IR sensor to maintain activation of the IR sensor.

7. The display device of claim 6, wherein the controller is configured to:
based on receiving an optical signal indicating another input for driving of the display panel through the IR sensor, control the power circuitry to start driving of the display panel and the electronic component based on the power.

8. The display device of claim 5, wherein based on the electric isolation between the power system and the display device being started, standby power of the display device reduced based on power measured from the power system after the input.

9. The display device of claim 2, wherein the heat generating element comprises:
a coil assembly comprising:
coils engaged to each other to be mutually coupled to each other; and
diodes respectively connected to distinct ends of the coils, and
wherein the first surface of the thermoelectric element is attached on a surface of the coil assembly where the diodes are positioned.

10. The display device of claim 1, wherein the PCB comprises:
a penetration hole at least partially overlapping the heat generating element positioned on the PCB,
wherein the first surface of the thermoelectric element is in contact with the heat generating element through the penetration hole of the PCB.

11. The display device of claim 1, wherein the heat generating element comprises:
backlight light emitting diodes (LEDs) configured to emit light toward the display panel;
wherein the first surface of the thermoelectric element is at least partially attached to the backlight LEDs arranged along a length direction of the display panel.

12. The display device of claim 1, further comprising:
a system on a chip (SoC) comprising circuitry configured to drive of the display panel;
a heat sink; and
another thermoelectric element comprising at least one electrode and having a third surface attached to the SoC and a fourth surface attached to the heat sink,
wherein the battery is coupled in series with the thermoelectric element, and the another thermoelectric element.

13. The display device of claim 1, wherein the PCB comprises:
a first portion where the heat generating element is mounted, and a second portion surrounding the first portion,
wherein the first portion comprises a metal.

14. The display device of claim 1, further comprising:
charging circuitry configured to control charging of the battery based on power generated by the thermoelectric element,
wherein the charging circuitry is configured to adjust an electric current input to the battery to maintain generation of the power by the thermoelectric element.

15. The display device of claim 1, wherein the thermoelectric element comprises:
a plate including the first surface attached to the heat generating element;
a n-doped semiconductor extending from a first portion on a third surface of the plate opposite to the first surface, toward the second surface; and
a p-doped semiconductor extending from a second portion on the third surface that is spaced apart from the first portion on the third surface of the plate, toward the second surface.

16. A display device comprising:
a controller comprising circuitry;
power circuitry configured to obtain power from a power system from outside of the display device for driving of the display device;
an infrared (IR) sensor;
a display panel;
a thermoelectric element including at least one electrode configured to at least partially convert heat energy of at least one of the controller or the power circuitry into electric energy; and
a battery configured to store the electric energy;
wherein the controller is configured to:
receive a first input to cease provision of an image through the display panel; and
based on the first input:
deactivate the display panel and the power circuitry; and
based on the deactivation, activate the IR sensor using the electric energy stored in the battery to detect a second input configured to start provision of an image through the display panel through the IR sensor.

17. The display device of claim 16, further comprising:
a chassis configured to support the display panel,
wherein the thermoelectric element comprises:
a first surface attached to at least a portion of the power circuitry; and
a second surface attached to the chassis.

18. The display device of claim 16, wherein the controller is configured to:
based on receiving the input, control the power circuitry to reduce standby power of the display device measured by the power system.

19. The display device of claim 16, wherein the controller is configured to:
in response to detecting a signal indicating the second input through the IR sensor, control the power circuitry to start driving of the display panel based on power of the power system.

20. The display device of claim 16, wherein the power circuitry comprises a coil assembly comprising:
coils engaged to each other to be mutually coupled to each other; and
diodes respectively connected to distinct ends of the coils, and
wherein a surface of the thermoelectric element is attached to a surface of the coil assembly where the diodes are positioned.
